(19) United States
(12) Patent Application Publication
(10) Pub. No.: US 2008/0315175 A1
(43) Pub. Date: Dec. 25, 2008

(54) ALIGNMENT, TRANSPORTATION AND INTEGRATION OF NANOWIRES USING OPTICAL TRAPPING

(75) Inventors: Peter Pauzauskie, Oakland, CA (US); Alexandra Radenovic, Zagreb (HR); Eliane Trepagnier, Palo Alto, CA (US); Jan Liphardt, Berkeley, CA (US); Peidong Yang, El Cerrito, CA (US)

Correspondence Address: JOHN P. O'BANION;O'BANION & RITCHEY LLP, 400 CAPITOL MALL SUITE 1550, SACRAMENTO, CA, 95814, US

(73) Assignee: THE REGENTS OF THE UNIVERSITY OF CALIFORNIA, Oakland, CA (US)

(21) Appl. No.: 12/139,205

(22) Filed: Jun. 13, 2008

Related U.S. Application Data
(63) Continuation of application No. PCT/US2006/062727, filed on Dec. 29, 2006.
(60) Provisional application No. 60/755,283, filed on Dec. 30, 2005.

(51) Int. Cl. B23K 26/20; H01L 29/12

(52) U.S. Cl. 257/12; 219/121.64; 257/E29.07

(57) ABSTRACT

Individually trapping, transferring, and assembling high-aspect-ratio semiconductor nanowires into arbitrary structures in a fluid environment. Nanowires with diameters as small as 20 nm and aspect ratios of above 100 can be trapped and transported in three dimensions, enabling the construction of nanowire architectures which may function as active photonic devices. Moreover, nanowire structures can now be assembled in physiological environments. In one aspect, nanowires are positioned to direct light to remote samples, reducing exposure of the overall sample to intense source illumination. A tunable nanowire probe for subwavelength imaging is also described utilizing efficient second harmonic generation (SHG) whose optical frequency conversion allows implementing subwavelength microscopes.

### CROSS-REFERENCE TO RELATED APPLICATIONS

This application claims priority to U.S. provisional patent application Ser. No. 60/755,283 filed on Dec. 30, 2005, incorporated herein by reference in its entirety.

### STATEMENT REGARDING FEDERALLY SPONSORED RESEARCH OR DEVELOPMENT

This invention was made with Government support under Contract No. DE-AC-02-05CH11231 awarded by the Department of Energy. The Government has certain rights in this invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND OF THE INVENTION

1. Field of the Invention

This invention pertains generally to manipulation of nanowires, and more particularly to manipulating nanowires using optical trapping.

2. Description of Related Art

Semiconductor nanowires have received much attention due to their promise as building blocks of miniaturized electrical, nanofluidic and optical devices, including nanolasers, light emitting devices, and subwavelength optical waveguides. Although chemical nanowire synthesis procedures have matured and now reliably yield nanowires with specific compositions and growth directions, the use of these materials in scientific, biomedical, and microelectronic applications is greatly restricted due to a lack of methods to assemble nanowires into complex heterostructures with high spatial and angular precision.

Presently, several nanowire assembly techniques are being investigated, including electric and magnetic fields, laminar flow in microfluidic channels, and Langmuir-Blodgett compression. Although these techniques can align groups of nanowires, they lack the ability to control and assemble individual wires into two or three dimensional heterostructures.

Single-beam optical traps have been used for almost two decades to manipulate and interrogate micro and nanometer sized objects. Trapping of metallic nanocrystals was pioneered by Svoboda and Block in their demonstration of single-beam optical manipulation of a 36 nm diameter gold particle. More recently, it has been shown that CuO nanorods can be optically manipulated in two dimensions with a special optical trap potential (a line optical trap).

Accordingly a need exists for a system and method of transporting and aligning nanowires into three-dimensional heterostructures. These needs and others are met within the present invention, which overcomes the deficiencies of previously developed nanowire assembly systems and methods.

### BRIEF SUMMARY OF THE INVENTION

Optical traps are an appealing tool for semiconductor nanowire integration due to their ability to act in situ within closed aqueous chambers, their potential applicability to a broad range of dielectric materials, their spatial positioning accuracy (<1 nm), and the degree to which an optical trap's intensity, wavelength, and polarization can be controlled by readily available technologies such as tunable external cavity lasers, acousto-optic modulators and holographic optical elements.

An aspect of the invention is to use an infrared single-beam optical trap to individually trap, transfer, and assemble high-aspect-ratio nanowires (e.g., semiconductor, metals, organic materials, and so forth) into arbitrary structures in a fluid environment. Nanowires with diameters as small as 20 nm and aspect ratios of above one hundred can be trapped and transported in three dimensions, enabling the construction of nanowire architectures which may function in various capacities, including active photonic devices, passive photonic devices, optical probes, subwavelength microscopy, and so forth. Moreover, nanowire structures can now be assembled in physiological environments, offering novel forms of chemical, mechanical, and optical stimulation of living cells.

As an aid to understanding the present invention, information follows about some of the terms utilized within the specification and claims, however, it is to be appreciated that these are provided for convenience and not as a substitute for other recitations within the specification and claims.

“Sonication” is the process of applying sound, typically ultrasound, energy to achieve various purposes. This is typically applied in the laboratory through a “sonicator”, wherein sound is transmitted into a liquid within a bath, or trapping region. Other characteristics of the liquid and trapping region can be manipulated to alter sonication characteristics, such as viscosity, temperature, sonication frequency and so forth. Sonication agitates the nanowires/particles within the trapping region being sonicated, such as to loosen nanowires/particles adhering to portions of the trapping region.

The present invention can provide a number of beneficial aspects which can be implemented either separately or in any desired combination without departing from the present teachings.

Another aspect of the invention is to use single-beam optical tweezers to trap, place, and orient individual nanowires into multi-wire, three-dimensional assemblies with nanometer precision.

Another aspect of the invention utilizes a trapping beam to locally fuse various types of nanowires, such as to create semiconductor to semiconductor junctions, at precise locations within a three-dimensional stack.

Another aspect of the invention is to utilize a combination of various surface treatments and materials to assemble a two-dimensional nanowire waveguide that is capable of local excitation of fluorophores and/or the forming of a heterogeneous three-dimensional “log-cabin” nanowire structure.

In one beneficial embodiment, a nanowire assembly method comprises optically trapping a nanowire with an infrared single-beam optical trap, and attaching the nanowire to an organic or inorganic structure.

In another beneficial embodiment, a method for nanowire laser assembly comprises manipulating a nanowire with an infrared single-beam optical trap, and assembling the nanowire into an arbitrary structure in a fluid environment.

In another beneficial embodiment, an assembly comprises a nanowire and an organic or inorganic structure, wherein the nanowire and the organic or inorganic structure are assembled by optically trapping the nanowire with an infrared single-beam optical trap, and attaching the nanowire to the organic or inorganic structure.

In another beneficial embodiment, a nanowire assembly comprises a nanowire and an arbitrary structure, wherein the nanowire is manipulated with an infrared single-beam optical trap and assembled into the arbitrary structure in a fluid environment.

In one embodiment, the optical trap has a beam wavelength of approximately 1064 nm. In one embodiment, the nanowire is attached to an organic or inorganic structure by means of laser fusing. In one embodiment, the nanowire has an aspect ratio greater than approximately one hundred. In one embodiment, the nanowire has a diameter less than approximately 80 nm to 100 nm. In one embodiment, the nanowire comprises a semiconductor. In one embodiment, the nanowire is trapped in a fluid environment such as in water.

In another beneficial embodiment nanowires of KNb0₃ are utilized within a tunable nanowire probe for subwavelength imaging. Efficient second harmonic generation (SHG) from these nanowires provides a form of optical frequency conversion allowing the implementation of many novel forms of subwavelength microscopes.

In another beneficial embodiment nanowires are positioned through optical trapping to direct light to a remote sample that need not be exposed in toto to the intense illumination of the source.

Further aspects and embodiments of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic diagram of an optical tweezers instrument for nanowire trapping.

FIG. 2 is a schematic cross-sectional view of the chamber portion of the optical trapping instrument illustrated in FIG. 1.

FIG. 3 is a schematic flow diagram of the steps within a nanowire positioning method according to an embodiment of the present invention.

FIG. 4 is a graph of PSD sum signal fluctuations as a function of time for various laser power levels.

FIGS. 5-6 are optical images of a trapped nanoribbon.

FIG. 7 is an optical image of a trapped nanoribbon, with the inset showing two attached nanoribbons.

FIG. 8 is a graph of Fourier transforms of laser deflection signals of FIG. 4.

FIG. 9 is a graph showing corner frequencies of PSD sum signals as a function of laser power, GaN cross section, and aspect ratio.

FIG. 10 is a darkfield image of a GaN nanowire laser-fused to a SnO₂ nanoribbon, the inset of which is a scanning electron micrograph of the fused junction.

FIG. 11 is a schematic representation of a three dimensional nanowire assembly consisting of SnO₂ nanoribbons and GaN nanowires.

FIG. 12 is a schematic representation of an optical darkfield image of a GaN nanowire brought to a human cervical cancer cell (HeLa) by optical trapping.

FIGS. 13A-13B are images of bright field and fluorescence, respectively, of fluorescent beads placed directly on or near a SnO₂ nanoribbon resting on SU8 photoresist.

FIGS. 14A-14B are images showing the melting of a single silver nanowire.

FIG. 15 is an SEM image of KNbO₃ nanowires which are utilized according to an aspect of the present invention.

FIG. 16 is a graph of the XRD pattern of KNbO₃ nanowires, and which shows the unit cell structure of this material having spontaneous polarization parallel to the c-axis.

FIG. 17 is a TEM image of a KNbO₃ nanowire and its ED pattern.

FIGS. 18A-18B are HRTEM images of single KNbO₃ nanowires and a ED pattern (inset in FIG. 18B) with the zone axis of [100] in FIG. 18A and of [2-33] in FIG. 18B.

FIG. 19 is a schematic figure of a nanowire manipulation configuration according to an aspect of the present invention.

FIG. 20 is a graph of SHG spectra of single nanowires for FIG. 19, showing θ denoting the angle between the electric field vector of the polarized fundamental beam and the wire axis.

FIG. 21 is a graph of spectrum for both SFG and SHG signals from a single KNbO₃ nanowire according to the configuration of FIG. 19, also shown is a magnification (×10) of SHG signal on the left portion of the figure.

FIG. 22 is a graph of panchromatic wavelengths generated by the nonlinear optical processes within individual KNbO₃ nanowires according to the configuration of FIG. 19.

FIG. 23 is a schematic for a single-beam optical trapping instrument according to an aspect of the present invention.

FIG. 24 is a perspective view of the trapping region of FIG. 23, showing bright field (left) and SHG (right) representations of the trapped KNbO₃ nanowire.

FIG. 25 is a graph of observed spectra for KNbO₃ and Si nanowires as registered on the instrument of FIG. 23.

FIG. 26 is a schematic representation of an optically trapped KNbO₃ nanowire, shown with a set of associated field images.

FIG. 27 is a graph of spectral characteristics of POPO-3 and corresponding experimental data for the instrument of FIG. 23.

### DETAILED DESCRIPTION OF THE INVENTION

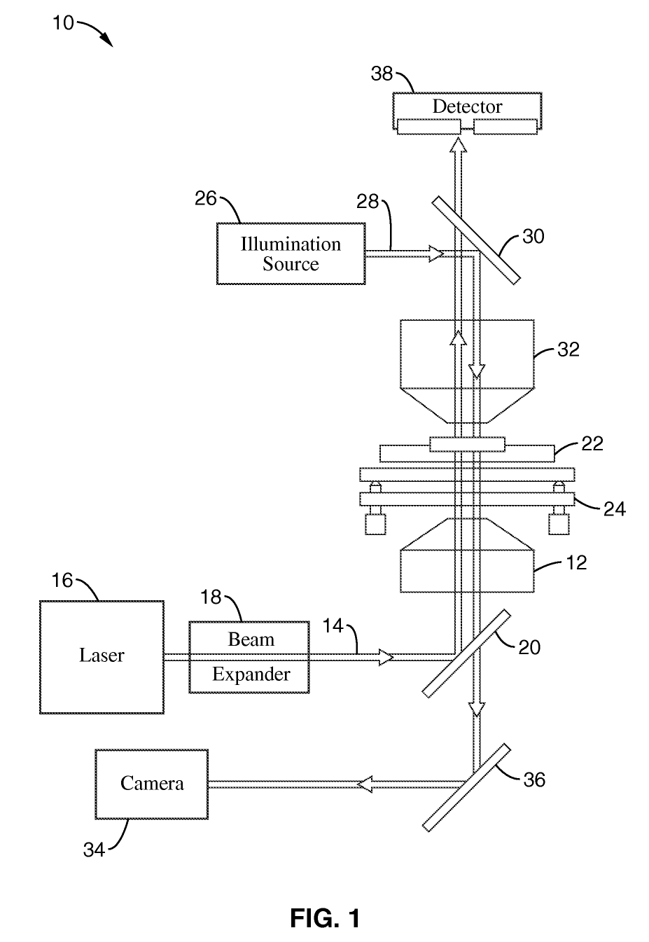

Referring more specifically to the drawings, for illustrative purposes the present invention is embodied in the method and apparatus generally shown in FIG. 1 through FIG. 27. It will be appreciated that the method and apparatus may vary as to configuration and as to details of the parts, and that the method may vary as to the specific steps and sequence, without departing from the basic concepts as disclosed herein.

### INTRODUCTION

In the Mie limit, applicable to objects with a dimension (D) that is much larger than the wavelength (λ) of light, D>>λ, ray-tracing methods can be used to calculate the forces exerted on the object by an optical potential (e.g., from an optical trap). Optical trapping of objects much smaller than the wavelength of light, such as certain glass nanorods, is theoretically tractable using the standard framework of the Rayleigh limit. However, nanowires targeted for use in integrated optical and electrical circuits usually have aspect ratios larger than one hundred and diameters smaller than 80 nm (two dimensions in the Rayleigh limit, and the third in the Mie limit), may have asymmetrical cross-sections, non-zero absorption, and typically have poorly characterized polarizabilities. These properties of semiconductor and metallic nanowires make it difficult to model their confinement by an optical potential. Therefore, we first determined whether a range of nanowires could be stably trapped with a simple single-beam optical trap.

### Manipulation of Nanowires Using Optical Trapping

Trapping experiments were performed in a purpose-built single-beam optical tweezers system with a fixed trap and a 3-axis piezo-electric nanopositioning stage employing closed-loop position feedback. To minimize thermal drift and vibration-induced wire alignment errors, we used an inverted geometry in which the nanopositioning stage body was directly bolted to an optical table. The system was constructed so that the trapping chamber could be moved coarsely in the x and y directions with a manual translation stage, and finely in all three axes with an xyz-piezo stage.

FIG. 1 is a schematic diagram of our experimental system 10, which was built around a Nikon 60× microscope objective 12 (e.g., CFI PLAN APO 60×WI NA 1.20 WD 0.22MM, Nikon part number 93109). A 1.6 mm diameter infrared (IR) beam 14 is generated from a laser 16 (e.g., 1064 nm, 2 W Laser, Coherent COMPASS 1064 2000N), expanded to 16 mm using a beam expander 18 (e.g., BE10; Thorlabs), and directed to objective 12 by mirror 20 where it overfills the back focal plane of the objective. The IR beam 14 impinges on a downstream position sensitive detector (PSD) 38 that is used for sensing motion of a specimen held in trapping chamber 22. The trapping chamber is positioned in the object plane and can be moved coarsely along x and y directions with the manual translation stage (not shown), and finely with the xyz-piezo stage 24 (e.g., Nano-UHV100; Mad City Lab, Madison, USA). The piezo stage used had 100 μm of travel along x and y directions and 25 μm in the z direction, was interfaced to the computer through a DT9834 USB module (Data Translation, Inc. —not shown), and controlled through software (not shown). Also shown in FIG. 1 is an illumination source 26 which emits a beam of light 28 for illuminating the specimen. The beam of light is directed by mirror 30 through a condenser 32, trapping chamber 22, and objective 12, where it is further directed to an imaging device 34 (e.g., CCD camera) via mirror 36.

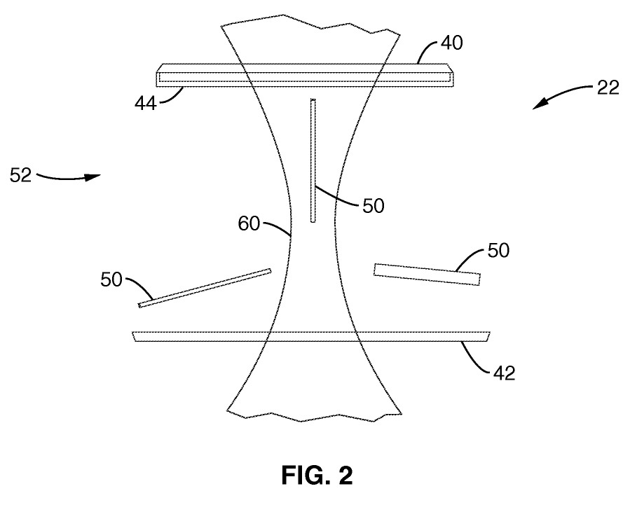

FIG. 2 illustrates the trapping chamber 22 of FIG. 1 comprising a quartz coverslip 40 and a glass slide 42. The quartz coverslip 40 comprises a 170 μm thick synthetic fused silica, the underside of which is coated with a thin (<<1 μm) lysine film 44 (e.g., poly-L-lysine for compatibility with living cells) or a thin gold film (e.g., about 1.7 nm deposited by standard thermal evaporation techniques). The glass slide is a standard #1 thickness rectangular glass slide. Quartz was used as the coverslip material to minimize autofluorescence during subsequent optical excitation of assembled structures. The edges of the glass slide and the quartz coverslip were then sealed with a 100 μm thick adhesive tape (not shown). Poly-L-lysine was purchased from Ted Pella, Inc., and the quartz coverslips were obtained from SPI (Thickness #1 (0.15 to 0.18 mm thick), 25 mm diameter, part number 01019T-AB).

Nanowires 50 (e.g., GaN, SnO₂, ZnO, Si and Ag) were chemically grown using conventional growth techniques and were suspended in deionized water via sonication. Several microliters of the nanowire-water suspension 52 were then pipetted into the trapping chamber. After sealing the chamber, the free nanowires sank to the bottom surface where they could be picked up with the optical trap. The nanowires sank due to gravity, consistent with their density and macroscopic dimension (typically >10 μm) in the long axis, which prevents stable colloidal dispersion. A wire with 100 nm diameter and 15 μm length has a mass of approximately 1 pg, and accounting for buoyancy, a force of a least 5 fN is needed to lift the wire off the surface of the glass slide 42.

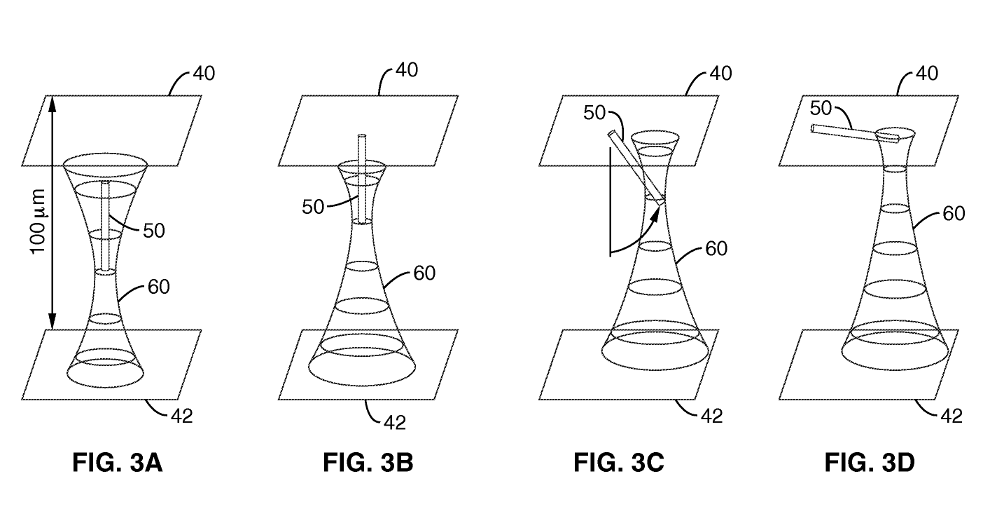

We found that stable trapping was greatly facilitated when the nanowires were picked up by aiming the laser trap 60 at one of the nanowire's ends, and then translating the trap along the wire while simultaneously raising the trap. The motion of the optical trap with respect to the nanowire rotated the wire off the bottom surface of the trapping chamber and led to a stably trapped configuration oriented along the optical axis as illustrated in FIG. 2 and in FIG. 3A. Once the nanowire was trapped stably, translation was performed with either the coarse manually operated translation stage for long (mm) distances or the three-axis piezo-stage for fine (nm) control. Velocities of ˜10 μm/s were routinely achieved in all three axes, as were mm scale translations.

We also observed that the nanowires were not only confined in 2D, but in all three dimensions, which facilitates controlled assembly. Since the wires were confined in all three dimensions, it was possible to pick them up from the bottom chamber surface and to bring them to the top chamber surface (at least 100 μm away). The free nanowires at the lower surface were thus well separated from the top surface, where nanowire characterization and assembly was possible.

From the ease of wire pick-up and the maximum wire translation velocity (˜10 μm/s), we found that GaN, Si, and SnO₂ have similar trapping properties. ZnO wires, on the other hand, are easier to pick up and can be translated at velocities of >20 μm/s without escaping from the trap. We did not observe aggregation of semiconductor nanowires in our optical trap, presumably because free nanowires quickly sank to the bottom coverslip surface, and because a nanowire must be aligned with the traps' optical axis for stable confinement.

FIG. 3A through FIG. 3D illustrate a nanowire trapping process. Once the nanowire was trapped and hovered in the upper portion of the trapping chamber as illustrated in FIG. 3A, we were able to further manipulate the position of each trapped nanowire 50 by raising the wire to the lysine coated top surface of coverslip 40 and pushing the end of the wire onto the lysine coating as illustrated in FIG. 3B. The wire, now docked to coverslip 40 by one end, was then rotated about the tethered end by trapping and translation of its free end as illustrated in FIG. 3C. Once the desired azimuth angle is achieved, the wire is laid flat and laterally docked to coverslip 40 by bringing its free end to the surface of the coverslip as illustrated in FIG. 3D.

### EXAMPLE 1

When the laser trap was brought close to GaN, SnO₂, ZnO, or Si nanowires, they were pulled into the trap. The ZnO, Si and circular cross section GaN wires trapped stably, with one end of the wire in the laser focus and the rest of the wire parallel to the optical axis. Despite their lack of three mutually orthogonal symmetry planes, GaN nanowires with isosceles cross sections also trapped stably, in part due to their subwavelength cross section (as low as 20 nm). However, ˜6.5% of N=200 tin oxide ribbons exhibited unexpected periodic oscillations. In contrast to the semiconducting wires, silver nanowires were not stably confined and also exhibited significant thermal instability. The observed behaviors of the nanowires in contact with the laser trap thus ranged from no trapping (silver), stably trapped but oscillating (some SnO₂), and stably trapped with no oscillations (GaN, ZnO, Si, and most SnO₂) (Table 1).

### EXAMPLE 2

Next, we characterized the unanticipated oscillations of trapped tin oxide (SnO₂) nanoribbons. Several studies have reported rotation of trapped objects by varying the phase, polarization, or mode of the laser beam. Here, however, the phase, polarization, and mode of the laser beam were fixed throughout the experiment. In our analysis of the ribbon's dynamics, we used the PSD sum signal in combination with frame-by-frame analysis of low bandwidth (30 Hz) video recordings of the ribbons.

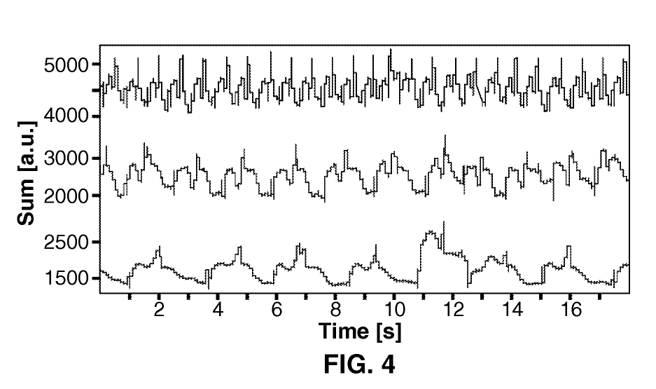

FIG. 4 shows position sensitive detector (PSD) sum signals (laser deflection signals downstream of the trapped nanoribbons) for trapping powers of 180 mW (lower trace), 240 mW (middle trace) and 360 mW (upper trace). Each trapped state corresponds directly to an observed laser deflection. Of N=200 tin oxide ribbons that were trapped, ˜5% oscillated between two states, and a further 1.5% visited as many as six different states per cycle (e.g., rare, coupled SnO₂ nanoribbons, illustrating their complex dynamics).

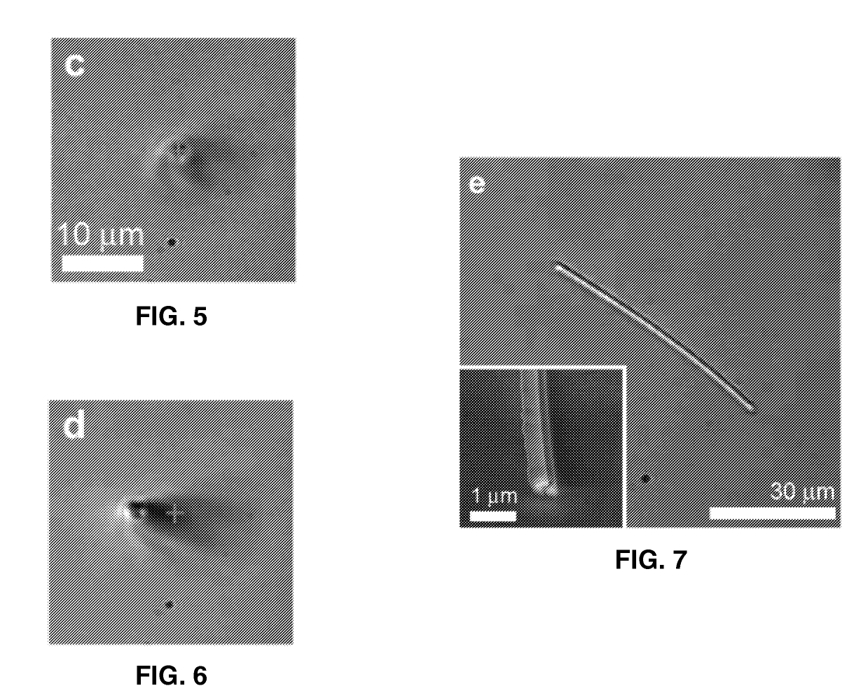

FIG. 5 and FIG. 6 are optical images of a trapped nanoribbon in two visibly distinct trapped states.

FIG. 7 is an optical image of what appears to be a single trapped nanoribbons, but the inset SEM image reveals that what appears to be a single nanoribbon is actually two attached nanoribbons.

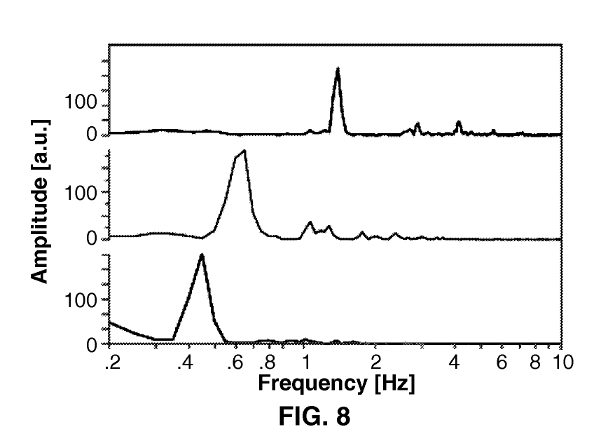

FIG. 8 shows the Fourier transforms of the laser deflection signals in FIG. 4. Analysis of the PSD sum signals in FIG. 4, as well as the Fourier transforms in FIG. 8 showing the frequency shift as a function of laser power, revealed that the period of oscillation was a linear function of the laser power. The rectangular SnO₂ ribbons thus exhibited much richer trapping dynamics than radially symmetrical objects such as polystyrene beads, since their symmetry prevents generation of net torque by the trap. Further analysis revealed that the most complex oscillations are related to the asymmetric cross section of coupled SnO₂ ribbons.

To investigate the hypothesis that the asymmetry of the SnO₂ nanoribbons was causing the oscillations, individual ribbons were trapped, their dynamics determined, and then attached to the poly-L-lysine surface and imaged with SEM. In the rare cases where numerous oscillation intermediates were seen (FIG. 5 and FIG. 6), SEM micrographs revealed that the trapped object consisted of a two-ribbon bundle. The more frequent cases with two oscillation intermediates corresponded to individual SnO₂ ribbons lacking visible defects. These results suggest that the oscillations of trapped tin oxide nanoribbons are in part due to their cross section, although other factors are clearly important, since otherwise all trapped single tin oxide ribbons would exhibit two state oscillation. A full theoretical treatment of SnO₂ nanoribbon trapping dynamics is difficult due to the ribbon's electronic properties and size and shape, which precludes a simple ray-optics treatment and places it a region combining both Rayleigh and Mie criteria.

A potential alternative source of the oscillations was excluded by placing a Faraday-effect optoisolator into the beam path, which suppresses laser instability (mode-hopping) due to back-reflections from the trapped wires into the laser cavity.

### EXAMPLE 3

We also characterized the GaN wires. Since their trapping properties are similar to Si and SnO₂, GaN wires possess a particularly large aspect ratio, and two cross sections are available (e.g., circular and triangular). To characterize the trap potential confining the GaN wires, we measured the corner frequency of the fluctuations of the trapped wires by fitting the power spectrum. Wire dynamics were obtained by collecting the light from the laser trap on a position sensitive photodetector (PSD).

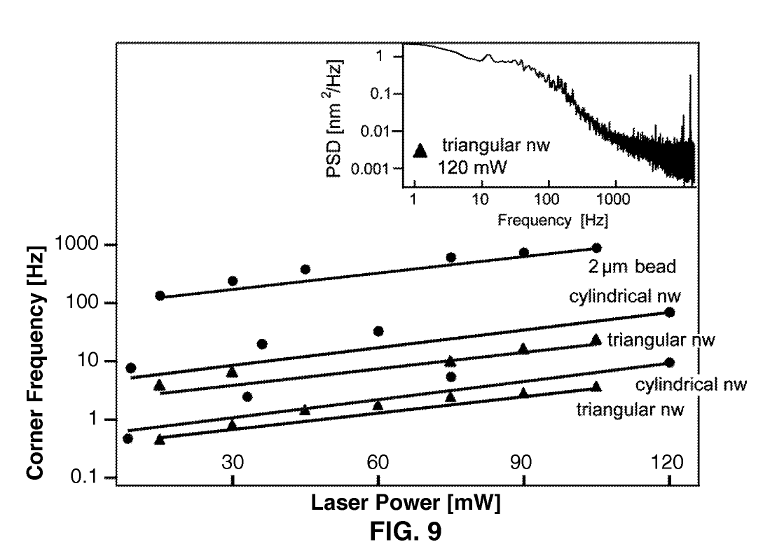

FIG. 9 is a graph showing corner frequencies of PSD sum signals as a function of laser power, GaN cross section, and aspect ratio, which ranged from 60 to 300 Hz (GaN triangular (lowest trace): 60 Hz; GaN triangular (second trace from bottom): 160 Hz; GaN cylindrical (third trace from bottom): 300 Hz; GaN cylindrical (first trace from bottom): 100 Hz. The upper trace shows a 2 μm polystyrene bead, and the inset shows the power spectrum of PSD sum signal fluctuations for a GaN nanowire trapped at 120-mW power.

From FIG. 9 it can be seen that the power spectrum of trapping light collected on the PSD was well fit by a Lorentzian (FIG. 9, inset) whose corner frequency depended on the laser power, and the cross section and aspect ratio of the GaN wire. At a laser power of 60 mW, cylindrical GaN nanowires with a 50 nm radius and ˜20 μm length were confined by an optical potential with a spring constant of ˜10⁻³ pNnm⁻¹, about 10 to 100 fold less than a micron sized polystyrene bead.

### EXAMPLE 4

Having established that semiconductor nanowires and ribbons could be stably trapped, we assembled two structures, (a) a nanoribbon waveguide, capable of local excitation of fluorescent beads typically used in biological applications, and (b), a three-dimensional, heterogeneous, stacked nanowire “log cabin” that is similar to the structures that comprise conventional integrated circuits.

### EXAMPLE 5

We used a micropositioner to place a long (>500 μm) SnO₂ nanoribbon, a low-loss and highly flexible subwavelength optical waveguide, across several SU8 photoresist platforms microfabricated onto quartz cover slips using standard photolithography techniques. We then grabbed a 2 μm diameter fluorescent polystyrene bead with the optical trap and placed it against the SnO₂ nanoribbon. Once the materials had been arranged, ultraviolet light (325 nm) was injected into the SnO₂ nanoribbon by focusing a continuous wave UV laser (5 mW) onto the ribbon's end. UV light of this wavelength excites the ribbon's intrinsic white photoluminescence, which then propagates along the length of the waveguide. Upon UV irradiation of the ribbon, the fluorescent bead, although located 300 μm from the site of UV injection, emitted green light. By contrast, fluorescent beads that did not touch the ribbon, and instead were placed at radial distances between 0.2 μm and 10 μm from the waveguide, did not fluoresce. Thus, the green fluorescence of the bead touching the ribbon was due to excitation by the evanescent field originating at the waveguide-water interface, rather than direct UV excitation. At these wavelengths, the 1/e decay distance of the evanescent field is less than 100 nm.

### EXAMPLE 6

Assembly of larger, and especially three dimensional structures, requires not only manipulation of individual wires, but also the controlled connection of one wire to another. Based on a simple order-of-magnitude calculation, we reasoned that it might be possible to locally fuse two wires, creating a junction whose properties depend on laser wavelength, the duration of irradiation, and the laser fluence. For example, a typical SnO₂ ribbon with a cross-section of 5000 nm², heat capacity of 338 J/kg K, and an IR absorption of ˜30% should, in the absence of any losses, experience a temperature rise of order 10¹⁰ K/s in the focus of a 1 W IR laser beam with a 1 μm waist. Thus, in those conditions the temperature of a trapped nanoribbon should rise rapidly to near or beyond its melting temperature (1900 K), though such heating will be substantially attenuated by the aqueous bath and radiative losses.

### EXAMPLE 7

We observed that it is possible to locally fuse two wires by way of the focused IR beam. Upon laser irradiation of the crossing point of two wires for five seconds using higher power (˜1 W) than for trapping, the two wires stopped moving with respect to one another and could not be pulled apart, presumably because they had been fused at the crossing point. Based on a simple order-of-magnitude calculation, it is possible that local temperatures at the junction can approach the melting point of GaN and SnO₂. Thermal fusing is consistent with our prior electron microscopy investigations which demonstrated that nanowires can be melted and welded at temperatures lower than required for bulk materials. Additionally, at the highest powers, water vaporized into small bubbles, limiting the maximum intensity used in forming the connection because of perturbations from the bubble.

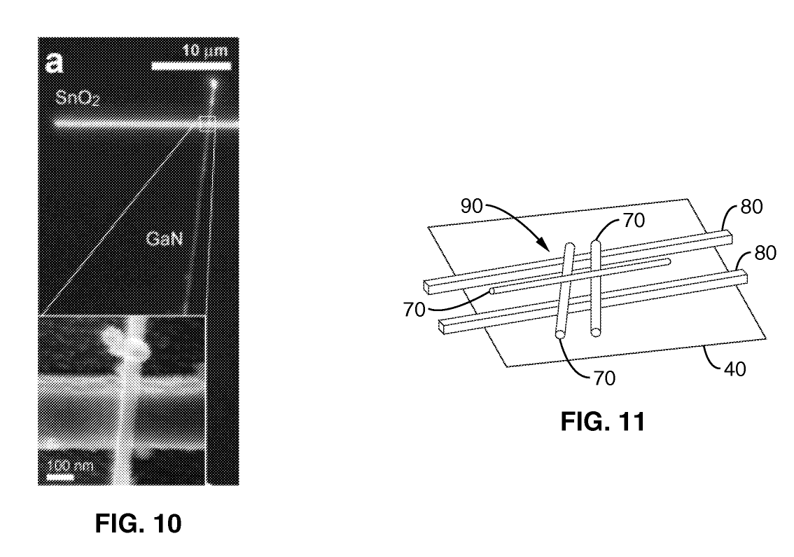

FIG. 10 depicts scanning electron microscopy of the nanowire-nanowire junctions created without water vaporization reveals no visible ablation or damaged by laser fusing. It will be noted that FIG. 10 is a darkfield image of a GaN nanowire laser-fused to a SnO₂ nanoribbon, while the inset is a scanning electron micrograph of the fused junction, showing that it is not visibly ablated. The presence of gold droplets generated from the gold coated coverslip during laser fusing are also visible.

### EXAMPLE 8

Having arrived at a method for manipulating, positioning, and locally fusing nanowires, which we call laser nanowire assembly (LNA), we built a three dimensional nanowire heterostructure on the top surface of the trapping chamber. We used two materials, GaN and SnO₂. SnO₂ nanoribbons function as passive waveguides, and GaN wires are subwavelength UV nanolasers, which may exploit 1D quantum confinement of carriers to achieve high optical gain and a low lasing threshold.

FIG. 11 illustrates a structure assembled from three GaN nanowires 70 and two SnO₂ nanoribbons 80 which were combined wire by wire, yielding a ˜300 nm tall “log cabin” 90 consisting of waveguides and nanolasers and with six individually optically fused junctions where the nanowires and nanoribbons contact each other. Log cabin 90 is shown on a base 40, such as of SnO₂ material, in this case having a size of approximately 50 nm by 100 nm. Using the procedure illustrated in FIG. 3, each wire was trapped as it hovered on the lower surface of the chamber, raised to the lysine coated top surface (FIG. 3A), and then pushed onto the lysine coating (FIG. 3B). The wire, now docked to the top coverslip by one end, was then rotated about the tethered end by trapping and translation of its free end (FIG. 3C). Once the desired azimuth angle with respect to other wires had been achieved, the wire was laid flat by bringing its free end to the surface (FIG. 3D).

More specifically, we produced this structure by first trapping free wires hovering near the lower surface of the chamber. Once a wire had been trapped and was pointing in the z-direction (perpendicular to the top and bottom chamber surfaces) it was moved to the poly-L-lysine coated top surface of the chamber. The end of the wire was then pushed onto the lysine coating, yielding a “fencepost” configuration in which the wire pointed straight down and was attached to the lysine coverslip at its end. The wire was then rotated about the tethered end by trapping its free end and translating it. Once the desired angle with respect to other wires had been achieved, the wire was laid flat by bringing its free end up to the surface. This process was repeated until the structure consisting of nanolasers (GaN) and waveguides (SnO₂) had been completed.

We based our design of this structure on the geometry of typical copper wire interconnects found in high density integrated chips. In our “log cabin”, we achieved an interconnect density of about 1-10% of that available with the current lithographic process (˜75 junctions/μm³). With relatively simple improvements to our instrument, primarily automation of the assembly process, interconnect densities should approach the theoretical limit defined by the cross section of the wires. Another desirable refinement of this method is to use holographic optical tweezers, which are capable of simultaneously creating and steering numerous independent traps, facilitating highly parallel manipulation and assembly of nanowires. The ability to rapidly assemble wires of various compositions with high spatial and angular precision should enable large scale integration of complex optoelectronic circuitry based on semiconductor nanowires.

### EXAMPLE 9

A particular advantage of the nanowire assembly procedures described above is that they are performed in water. For some applications, such as the construction of integrated optoelectronic switches, the water will need to be removed post-assembly, which should be performed at a sufficiently slow rate. Rapid drying (e.g., by warming the sample or using a vacuum desiccator) was found to be problematic, since it leads to the formation of bubbles that can damage stacked nanowire structures. For a broad range of applications, however, the compatibility of laser trapping based assembly with aqueous environments is essential. In biomedical or biodetection applications where semiconductor sensors, nanowaveguides, and nanolasers are to be assembled near or in contact with living cells and tissues, the entire process will need to be accomplished in water, at room temperature, and at physiological ionic strength and pH.

### EXAMPLE 10

A primary motivation for our choice of trapping wavelength (1064 nm) was that living cells can tolerate limited IR laser irradiation. Optical imaging of biological samples benefits from a well behaved and local excitation source. We found that optically trapped nanowires (in this case, a single GaN nanowire with a cylindrical cross-section) can be positioned with respect to living cells. HeLa tissue culture cells were grown on poly-L-lysine coated quartz coverslips and chambers were assembled as before. Using LNA, two complementary approaches can be immediately realized. As shown in FIG. 8, optically trapped nanowires (e.g., a cylindrical GaN nanowire) can be positioned with respect to living cells.

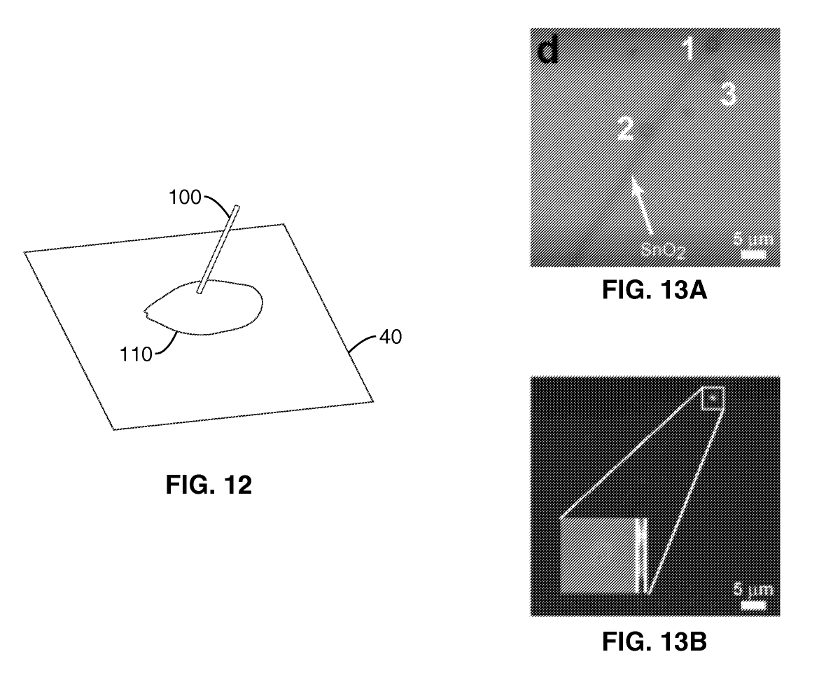

FIG. 12 is a schematic representation of an optical darkfield image of a GaN nanowire 100 (radius ˜30 nm) brought to a human cervical cancer cell 110 (HeLa) by optical trapping. Once positioned with respect to the cell, the wire was non-specifically attached to the membrane of the cell by pushing the wire against the membrane for several seconds. By way of example, a base 40 is shown, such as poly-lysine coated quartz.

### EXAMPLE 11

We found that it was possible to scan a trapped GaN nanowire across the cell membrane, and also to place one end of the nanowire against the cell membrane and maintain its position for arbitrary durations. GaN nanowires were used in these experiments since they lase as well as operating as a waveguide when appropriately pumped, suggesting their use as subwavelength illumination sources to image live cells and tissues by scanning the end of a GaN wire across a cell, or by pushing one end of the wire into the cell. In this way, local excitation of fluorophores, either by light radiating from the end of the wire or via the evanescent field originating at the wire/water interface, can be achieved. Therefore, in addition to the construction of three dimensional heterogeneous electronic and optical devices, new forms of optical imaging and stimulation of living cells can be imagined. For instance, trapped nanowires should be useful as subwavelength sources of second-harmonic illumination light in near-field scanning microscopy. Moreover, the small cross-section and very high aspect-ratio of these nanowires makes them particularly well-suited for delivering extremely localized chemical and mechanical stimuli to cells, and other localized areas.

FIG. 13A-13B are bright field and fluorescence images, respectively, of 2 μm yellow-green fluorescent polystyrene beads (Molecular Probes, Inc.) placed directly on or near a SnO₂ nanoribbon resting on SU8 photoresist. FIG. 13B shows wire-bead structure during UV excitation of the ribbon ˜300 μm from the bead. Fluorophores in bead 1, which touches the nanoribbon, are excited by the evanescent field created by waveguided photoluminescence generated elsewhere in the nanowire. Fluorescent beads that did not touch the ribbon, and instead were placed at radial distances of ˜500 nm (Bead 2) and ˜5 μm (Bead 3), did not fluoresce. At these wavelengths, the 1/e decay distance of the evanescent field is less than 100 nm.

Also, as shown in FIG. 13A and FIG. 13B, local excitation of fluorophores by an evanescent field (here with a 1/e decay distance of ˜100 nm) from a SnO₂ waveguide can be accomplished and suitably arranged SnO₂ ribbons can thus be used as local sources of excitation light in various imaging and bio-sensing geometries. Evanescent excitation by intrinsic white photoluminescence of the SnO₂ ribbon, and waveguiding of optically coupled nanolaser emission has recently been demonstrated elsewhere. Moreover, the small cross-section and very high aspect-ratio of the nanowires are suited for delivering extremely localized chemical, mechanical, and electrical stimuli to cells, based on the construction of integrated assemblies next to a cell of interest. Therefore, in addition to the three-dimensional heterogeneous devices that can be constructed from nanowires according to the LNA method of the present invention, this method should facilitate novel experiments for in situ characterization of biological materials.

### EXAMPLE 12

Our positioning accuracy was limited significantly by Brownian fluctuations. From the Equipartition theorem, the root-mean-squared transverse fluctuations of the GaN nanowires will be on the order of 10-60 nm (for laser powers ranging from 360-60 mW, respectively). In addition, drift of the optical trap with respect to the stage and the use of visible optics with intrinsic diffraction limits further degrade positioning accuracy. For optimal accuracy, a closed loop system exploiting fiduciary markers on the coverslip surface can be used. Also, provided that the wires are separated by more than half the wavelength of the illumination light, fitting of the point spread function of light scattered from a wire should allow its continuous localization during assembly with improved resolution. Nevertheless, the positioning accuracy and the level of multilayer registration achieved using our laser trapping method show significant improvement over those achievable with microfluidic channels or Langmuir-Blodgett techniques.

### EXAMPLE 13

The use of holographic optical tweezers, which are capable of simultaneously creating numerous independently steerable traps, can be utilized to further facilitate manipulation and assembly of complex nanowire structures. For applications such as the construction of integrated optoelectronic switches, the water or other solvent present during LNA will need to be removed after assembly (post-assembly). However, for biomaterials applications in which semiconductor sensors, nanowaveguides, and nanolasers are to be assembled proximal to living cells and tissues, the compatibility of LNA with aqueous environments is very beneficial, since assembly often needs to be performed in water, at room temperature, and at physiological ionic strength and pH.

### EXAMPLE 14

To characterize the trap potential confining the wires, we measured the corner frequency of the PSD signal fluctuations by fitting the power spectrum. The corner frequency, f₀, is related to the trap spring constant, κ, by f₀=κ/(2πγ), where γ is the drag coefficient of the trapped object. The PSD sum signal (sampling frequency, 10 kHz) is proportional to the total amount of light falling on the detector, which depends on the scattering properties of the trapped object, its position with respect to the trap, and the efficiency of the collection optics. Accurate estimation of the spring constant from the corner frequency measurements is difficult, since the PSD sum signal will be affected by lateral, angular, and longitudinal motions of the nanowire in the trap. Moreover, it is a nontrivial exercise to determine the drag coefficient, γ=6ηₒπR_{H}, where ηₒ is the dynamic viscosity of water, and R_{H} is hydrodynamic radius, of a nanowire. We estimated the drag coefficient using Perrin's formula,

$$\frac{{R}_{H}}{{R}_{S}} \frac{\sqrt{{p}^{2} - 1}}{{p}^{\frac{1}{3}} ln ( p + \sqrt{{p}^{2} - 1} )} ,$$

which gives the ratio between the hydrodynamic radius, R_{H} of cylinder and the hydrodynamic radius R_{S} of a sphere having the same volume, where p is the ratio between cylinder radius r and length L. Based on an average cylindrical wire diameter of 100 nm and an average length of 20 μm, we determined R_{H} of 2.1 μm using Perrin's formula and 1.9 μm using an alternate expression. Assuming that the predominant source of the PSD sum signal fluctuations are lateral motions of the nanowire in the trap, the spring constant at 60 mW power that trapped GaN wires experience is 10⁻³ pN nm⁻¹.

### EXAMPLE 15

Despite their small diameter (less than skin depth) and high polarizability, the silver nanowires did not trap stably. In practice, at both low and high powers, silver wires are observed to be repelled from the laser focal spot as it is brought near wires with the piezo controller. It is unlikely that the pentagonal cross-section of the silver nanowires prevented their trapping, given that GaN wires trapped stably with triangular cross-sectional symmetry. When the objective focal point was positioned on silver wires, and the laser turned on thereafter, wires were observed to have a significant thermal instability at the trapping wavelength (1064 nm), leading to rapid melting of the wires.

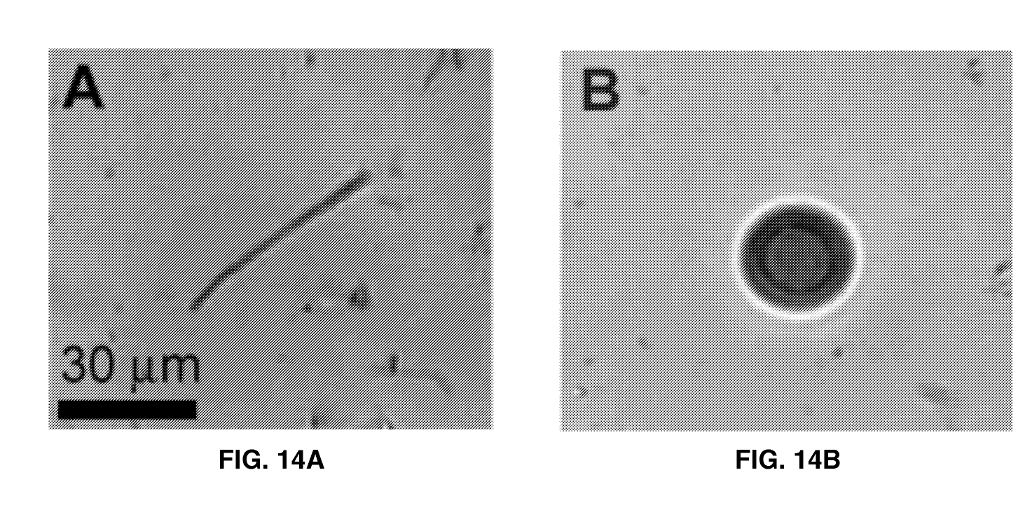

FIGS. 14A-14B are images, monitored with a 30 Hz video rate, show the melting of a single silver nanowire in the above manner. FIG. 14A-14B represent video frames roughly 200 ms apart with a steadily increasing laser power. In FIG. 14A, the wire is shown immediately before it melts. In FIG. 14B, the melted structure and the surrounding water bubble are all that remain of the wire.

As can be seen, therefore, an aspect of the present invention is that semiconductor nanowires with high-aspect-ratios (>100) and extremely small diameters (˜20 nm) may be trapped and transported in a highly focused laser beam (optical trap). The technique is independent of semiconductor composition, allowing for the integration of a range of different materials with various optical and electronic characteristics. Another aspect of the invention is the ability to address, fuse, and assemble individual nanowires together, one at a time, to create three-dimensional architectures, with unprecedented accuracy and precision. These capabilities may well find use in the microelectronics industry, where new techniques are needed to push beyond the size limits of optical lithography. It also opens up new opportunities in biological sciences where trapped nanowires can function as optically controlled scanning probes, or as a means of delivering chemical or mechanical stimuli to cells with extremely small contact areas.

From the forgoing, it should also be noted that nonlinear, laser-trapped nanowires can potentially be used as optical parametric oscillators (OPO). For example, a dense, holographic optical array of subwavelength OPOs is pertinent in signal processing and quantum communication through entangled photons.

Tunable Nanowire Optical Probe for Subwavelength Imaging

One crucial challenge for subwavelength optics has been the development of a tunable source of coherent laser radiation for use in the physical, information, and biological sciences that is stable at room temperature and within physiological environmental conditions. Semiconductor nanowires have diameters substantially below the wavelength of visible light and have unique electronic and optical properties that make them prime candidates for subwavelength laser technology. In this section, we describe the development of an electrode-free, continuously-tunable source of coherent visible light from individual potassium niobate (KNbO₃) nanowires that is compatible with physiological environments. These wires exhibit efficient second harmonic generation (SHG), and act as frequency converters, allowing the local synthesis of a wide range of colors via sum and difference frequency generation (SFG, DFG). We use this tunable nanometric light source to implement a novel form of subwavelength microscopy, in which an infrared (IR) laser is used to optically trap a nanowire and scan it over a sample. This technique enables the imaging of biological samples with high resolution and without engendering sample damage from direct laser irradiation.

In the following discussion, we demonstrate that the large second-order susceptibility, χ⁽²⁾, of KNbO₃ nanowires in facilitating the generation of tunable, coherent, visible radiation is sufficient for in situ subwavelength fluorescence microscopy. We chose the perovskite-oxide KNbO₃ as the nanowire material due to its biological compatibility, large effective nonlinear optical coefficients (d_{eff}=10.8˜19.6 pm/V at λ=1064 nm) at room temperature, large refractive indices (n=2.1˜2.5), as well as its transparency in a wide range of wavelengths including the visible spectral region.

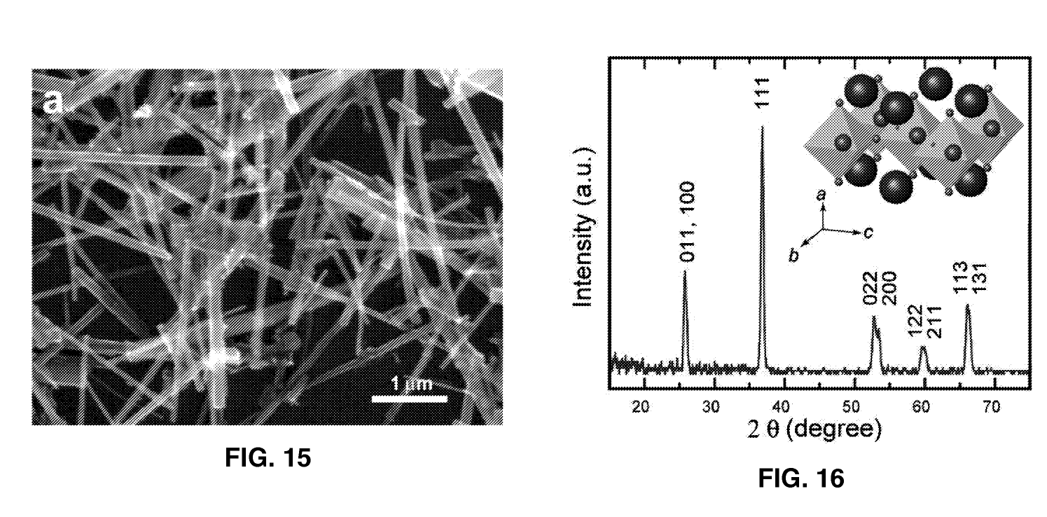

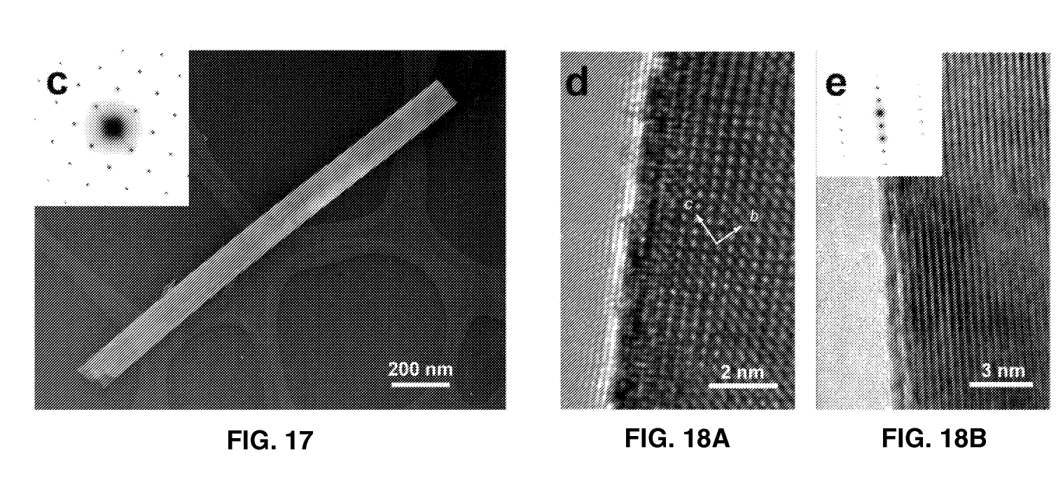

FIG. 15 through FIG. 18B illustrate aspects of single crystalline KNbO₃ nanowires which were synthesized using a hydrothermal method. These nanowires are characterized as orthorhombic phase (Amm2) with the growth axis parallel to [011] direction, wherein the polar c-axis is therefore 45 degrees off the nanowire axis. FIG. 15 is an SEM image of the synthesized KNbO₃ nanowires. FIG. 16 is a graph of an XRD pattern of the KNbO₃ nanowires. All peaks in the graph are shown indexed to orthorhombic KNbO₃ phase (Amm2). The inset within FIG. 16 shows the unit cell structure of this material whose spontaneous polarization is parallel to the c-axis. FIG. 17 is a TEM image of a KNbO₃ nanowire and its diffraction (ED) pattern (inset). The zone axis and the wire-growth direction are determined as [100] and [011] respectively. FIG. 18A-18B are HRTEM images of single KNbO₃ nanowires and a ED pattern with the zone axis of [100] in FIG. 18A and [2-33] in FIG. 18B. Growth directions are determined to be [011] in both images.

A desired characteristic of a versatile and useful nonlinear circuit element for integrated photonics is the ability of optical frequency-doubling via SHG, a second order nonlinear optical phenomenon. In this process, two photons with the fundamental angular frequency ω₁ are converted through nonlinear crystal polarization into a single photon ω₂ at twice the fundamental frequency (ω₂=2ω₁).

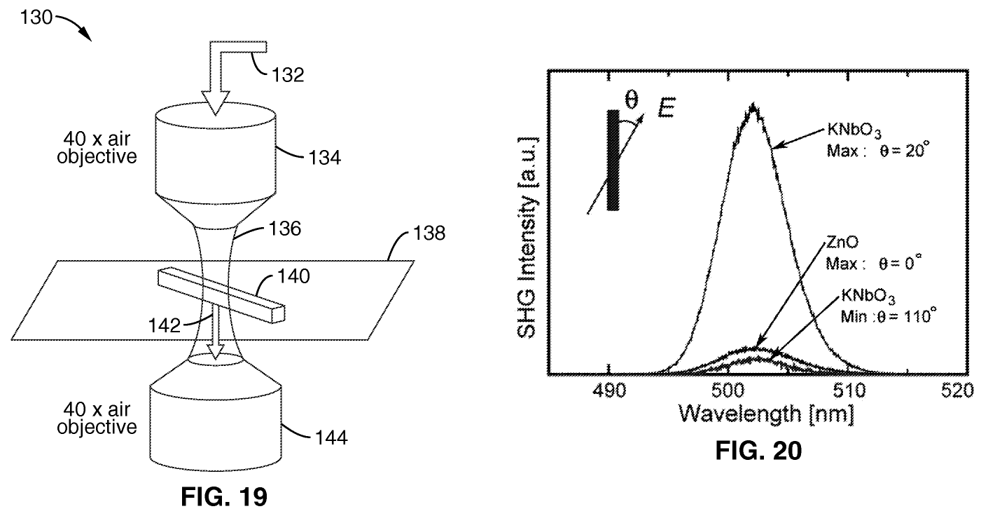

FIG. 19 illustrates an experimental setup 130 for utilizing femtosecond pulses to characterize the SHG response of single KNbO₃ nanowires. Beam 132 is shown passing through a first objective 134, such as a 40× air objective, from which optical trap 136 emanates, to pass through at least one optically transparent layer 138, such as a coverslip, proximal to which is retained one or more nanowires 140 being directed by trapping force 142. Beam 132 is shown entering a second objective 144, such as another 40× air objective.

FIGS. 20-22 illustrate the nonlinear optical properties of single KNbO₃ nanowires. In FIG. 20, the SHG spectra of single nanowires is shown with θ denoting the angle between the electric field vector of the polarized fundamental beam (λ=1004 nm, 18 kW/cm²), also referred to as polarization direction, and the wire axis. The SHG signal shows the two-fold symmetric θ-dependence with the intensity ratio (Max/min) of approximately 16.9.

The maximum SHG spectrum of a single ZnO nanowire is plotted as the middle line. The graph shows the observed SHG spectra (λ=502 nm) from a KNbO₃ nanowire (110 nm in diameter, 4 μm in length) generated by introducing the fundamental beam (λ=1004 nm, 18 kW/cm²). The SHG signal showed an intensity maximum when θ=20°, and a minimum with θ=110°. All SHG spectra from different nanowires had a similar dependence on θ, though θₘₐₓ changed slightly depending on the nanowires. Since orthorhombic KNbO₃ has a maximum SHG response when the polarization direction is parallel to the c-axis of the crystal, our results indicate that the angle between the c-axis and the nanowire axis varies slightly from nanowire to nanowire. This is due partly to differences in crystal orientations with respect to the incident laser, and possibly responsive to twinning planes.

The SHG spectrum observed from a typical ZnO nanowire (e.g., 120 nm in diameter, 15 μm in length) with the same configuration and tuned to θₘₐₓ=0° is also plotted for comparison in FIG. 20. Integration of the respective peaks reveals that the KNbO₃ nanowire produces 10.5 times more SHG signal than that of ZnO nanowire due to its higher effective nonlinear susceptibility. “Phase matching,” which increases the efficiency of nonlinear optical processes cannot be expected in this experimental configuration, thus the SHG intensity is proportional to d_{eff}². As d_{eff}=2.8 pm/V for ZnO nanowire, the value for a KNbO₃ nanowire can be estimated as d_{eff}=9.1 pm/V, which is slightly lower than that of a bulk KNbO₃ crystal, possibly due to the smaller number of probed unit cells in the nanowire.

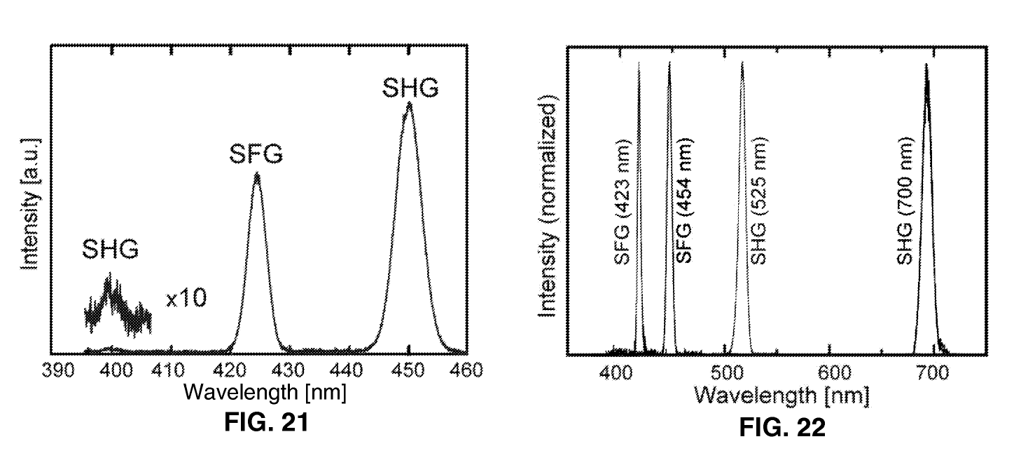

FIG. 21 depicts intensity spectrum including both SFG (423 nm) and SHG (400 nm, 450 nm) from a single KNbO₃ nanowire. The magnification (×10) of the SHG signal at 400 nm was also plotted (on the left of the graph). Two fundamental beams of λ=800 nm and 900 nm with the same powers (˜5 kW/cm²) were used.

Another aspect of providing a versatile nonlinear circuit element for use in nano-photonic applications is wave mixing, specifically SFG (ω₃=ω₁+ω₂) and DFG (ω₃=|ω₁−ω₂|). FIG. 21 shows the SFG signal (λ=423 nm) and the corresponding SHG signals (λ=400 nm and 450 nm) obtained from a single KNbO₃ nanowire by introducing two fundamental beams at λ=800 nm and 900 nm. This demonstrates the ability of nanowire frequency converters to create four different waves from two fundamental input frequencies ω₁ and ω₂:2ω₁, 2ω₂ and |ω₁±ω₂|. The DFG signal was not observed here because the expected wavelength (λ=7200 nm) is outside of current instrumental limits. The SHG signal at 400 nm was weak, probably due to the absorption within the nanowire, which was confirmed by the photoluminescence measurements showing an absorption edge at 376 nm with the strong green luminescence around 550 nm (data not shown).

FIG. 22 depicts panchromatic wavelengths generated by the nonlinear optical processes within individual KNbO₃ nanowires. The wavelength λ=423 nm was produced as a result of SFG: (423 nm)⁻¹=(800 nm)⁻¹+(900 nm)⁻¹, and other spectra were obtained as SFG: (454)⁻¹=(800)⁻¹+(1050)⁻¹, SHG: (525)⁻¹=2(1050)⁻¹, and (700)⁻¹=2(1400)⁻¹. This graph demonstrates the ability of KNbO₃ nanowires to generate light throughout the visible spectrum via the processes of SHG and SFG. Thus, these nanowires can create continuously-tunable and coherent visible light through nonlinear optical processes. Due to their efficient frequency doubling and wave mixing capabilities, as well as their subwavelength dimensions, tunable KNbO₃ nanowire light sources are likely to play an important role in bottom-up integrated photonic devices based on subwavelength cavities. Moreover, the properties of these nanowire sources immediately enables the development of a new form of light microscopy which is somewhat analogous to the widely used technique of two-photon fluorescence excitation, which is becoming an essential tool for visualizing biological processes within and around living cells and tissues. However, the requisite high laser intensities necessary with two-photon fluorescence excitation can result in cell damage and photobleaching and the technique works best with relatively thin samples. Consequently, observations are often limited to relatively short periods and to depths less than the thickness of a few cells.

One aspect of the invention is utilizing optical trapping to manipulate nanowires with high spatial accuracy in closed aqueous chambers to direct light remotely. The high χ⁽²⁾ coefficients of KNbO₃ nanowires are well suited for use in conjunction with optical trapping to generate light remotely in one end of the optically trapped nanowire and then to waveguide that light through the nanowire to the sample, thus reducing the bleaching and other damage to the samples. Ultimately, photons are emitted through the subwavelength aperture of the nanowire for direct excitation of the sample. Through these two processes a frequency-doubled coherent beam can be generated and waveguided to a point several micrometers removed from the focal point of the pump laser, wherein a means for direct, spatially-resolved, fluorescence imaging is provided without engendering optical damage from the high-intensities necessary for two-photon excitation.

One advantage of this strategy is that the nanowire aligns spontaneously with the optical axis of the trapping laser, allowing the entire nanowire volume to participate in the SHG. In addition, since the nanowire grows parallel to the [011] direction, phase matching is expected when using infrared wavelengths, such as 1064 nm. Infrared wavelengths of approximately 1064 nm are popular for optical trapping because of the tolerance of living cells to laser irradiation near this frequency. In principle, temperature controllers may also be used to adjust for optimal phase-matching conditions.

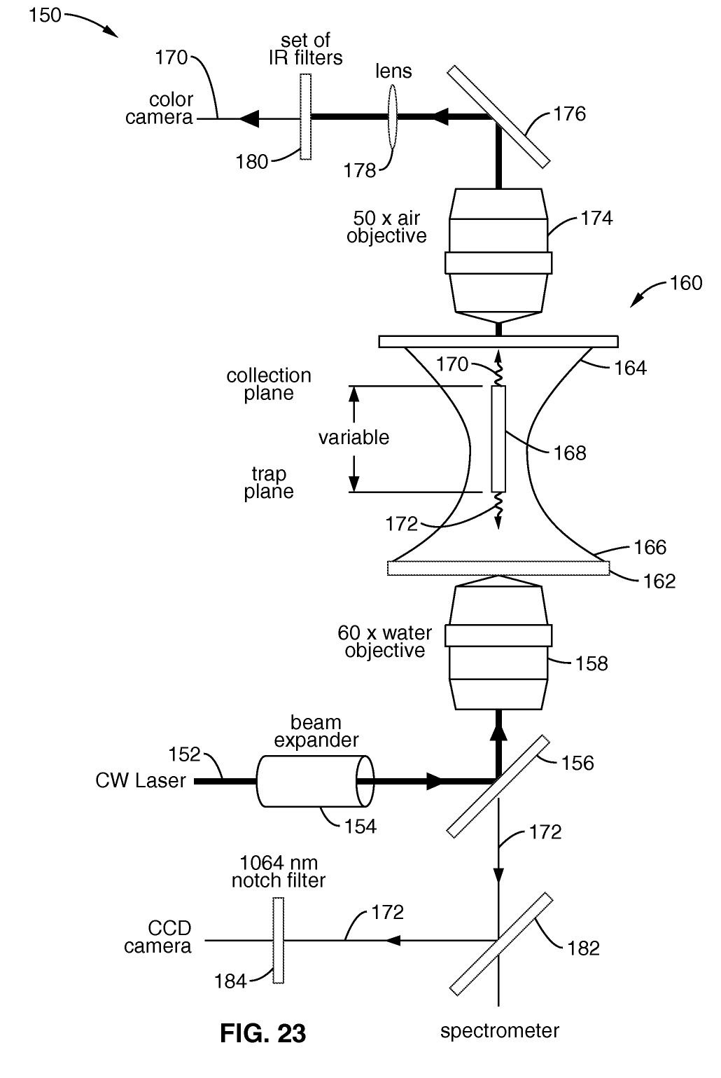

FIG. 23 depicts a detailed configuration 150 for a single-beam optical trapping instrument for second-harmonic generation (SHG) from optically trapped KNbO₃ nanowires. The setup of FIG. 23 is similar to that of FIG. 1 discussed previously. A laser beam 152 is shown passing through a beam expander 154 and being reflected from a first mirror 156 into a first objective 158, such as a 60× water objective. A trapping chamber 160 is shown, such as comprising a first transparent slide 162, second transparent slide 164 and trapping liquid 166 into which is suspended nanowires 168. Beams are generated from nanowire 168 comprising a bright field beam 170 (at a wavelength of 532 nm in this example), and an SHG beam 172 (at a wavelength of 1064 nm in this example).

Beam 152 and bright field beam 170 then pass into second objective 174, such as a 50× air objective and is afterward processed. In this example processing is shown as beam 152 and bright field beam 172 being reflected from second mirror 176 to pass through lens 178. Beam 152 is then blocked by filter 180 leaving bright field beam 170 directed toward an imager, such as a color camera. It should be noted that the SHG beam is shown passing back through first objective 158, first mirror 156 (e.g., a half-silvered mirror) to be reflected from a third mirror 182 to an imager, such as a CCD camera, while a portion of SHG beam 172 can be directed through a half-silvered third mirror 182 toward a spectrometer.

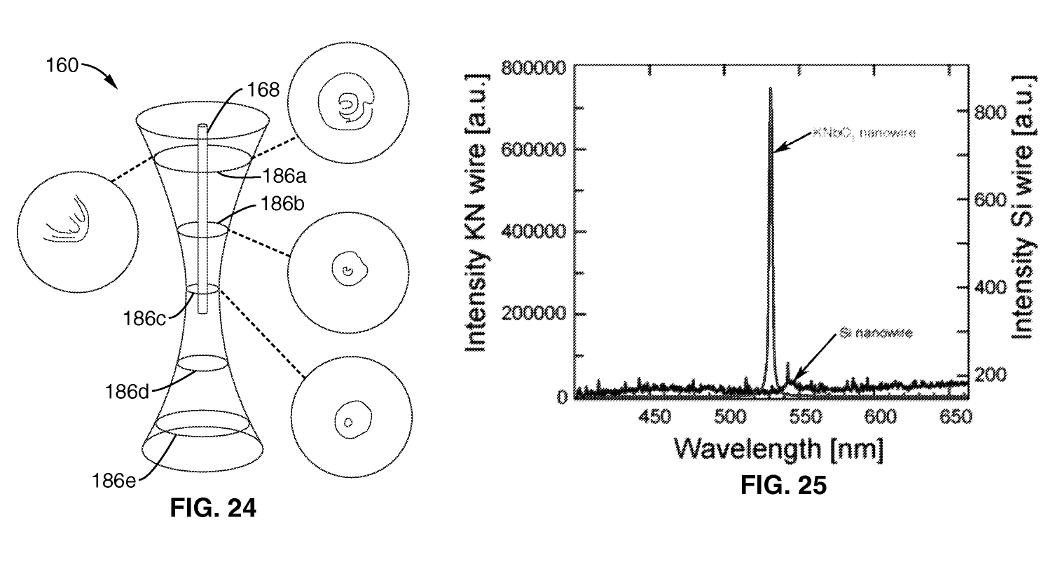

FIG. 24 illustrates both bright field images (left-side of figure) and SHG images (right-side of figure) of the KNbO₃ nanowire 168 in trapping region 160. Waveguiding of the SHG signal leads to Airy discs at the distal (top) end of nanowire 168 which acts as a subwavelength aperture. By way of example, five stations 186a-186e are shown along the length of trapping region 160.

As expected, an intense beam of green light was observed to radiate from the distal end of the trapped KNbO₃ nanowire (three images on right side). By changing the focus of the top objective along the growth axis of the nanowire, the radiation profile could be charted as a function of position. A diffraction-limited spot and corresponding Airy discs were observed at the distal end of the wire, revealing optical waveguiding away from the origin of photon conversion and emission from a diffraction-limited aperture.

FIG. 25 depicts observed spectra for KNbO₃ and Si nanowires characterized using the optical trapping instrument illustrated in FIG. 23. A strong SHG signal at λ=532 nm (green) is collected from the trapped KNbO₃ nanowire with intensity shown on the left axis, while no signal was registered from Si nanowires with intensity scale shown on the right axis.

The green emissions of FIG. 24 shown as the spike in FIG. 25 were analyzed and found to be the SHG signal with a wavelength at 531±1.8 nm. Similar measurements with ZnO (not shown) and Si nanowires did not produce any detectable SHG signals, indicating negligible second harmonic signal from symmetry breaking at the wire-water interface, as well as the suitability of KNbO₃ wires to act as subwavelength scanning probes.

Having demonstrated SHG and waveguiding in optically trapped KNbO₃ nanowires, we proceeded to further characterize the excitation volume affiliated with the geometry of the nanowire. The two-photon excitation volume, V_{exc}˜0.113(λ₁₀₆₄ₙₘ)³, is calculated to be less than twice the volume of a typical nanowire (100 nm in diameter, 9 μm in length), V_{NW}=0.058(λ₁₀₆₄ₙₘ)³.

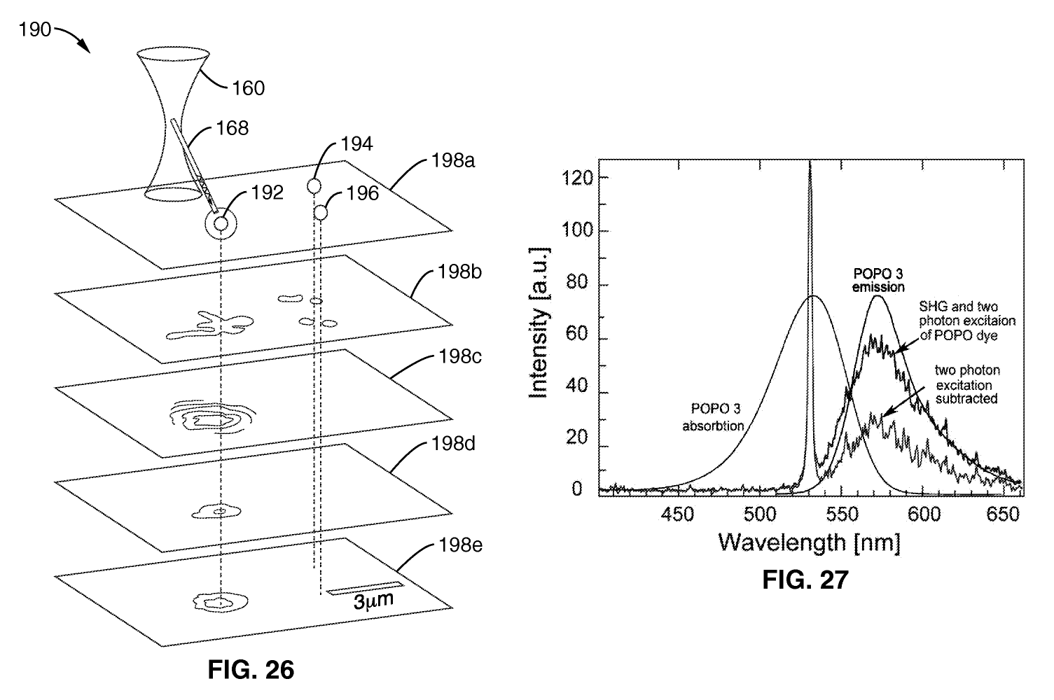

FIG. 26 illustrates POPO-3 bead excitation 190 by waveguided SHG signal from an optically trapped KNbO₃ nanowire 168 within trap 160. Nanowire 168 is shown in contact with left-most bead 192 within an inverted schematic drawing of the experimental configuration on plane 198a, such as a glass slide. Addition beads 194, 196 are also represented toward the right of plane 198a.

The ability of these nanowires to act as nonlinear fluorescence-excitation probes is demonstrated via excitation of an individual 1 μm-diameter fluorescent bead using frequency-doubled photons from an optically-trapped nanowire as was shown in plane 198a. In this configuration we optically trapped a single KNbO₃ nanowire 168 and brought the distal end in contact with a fluorescently labeled bead 192. Bright field optical image of the beads, with the nanowire in contact with the leftmost bead is represented by plane 198b which generated a remarkable orange fluorescence at the contact point. At plane 198c a color-CCD fluorescence image of plane 198b is shown generating green light emission from the nanowire and the orange emission from the bead.

A control image of the same beads with IR radiation in plane 198b is shown in plane 198d, but represented without a trapped nanowire. Removal of the nanowire caused a reduction in orange emissions from the bead by more than a factor of 80 as shown in plane 198d, which confirms that light generated in and emitted by the nanowire was the predominant source of excitation light. The intensity difference between planes 198c and 198d is created in response to digital subtraction of the red components from the images, which displays the distinctive fluorescence emission due to SHG-excitation from the optically trapped KNbO₃ nanowire.

In plane 198e a digital subtraction of image plane 198d from 198c is represented. It should be noted that the term “plane” in the above instances does not connote any sequential locations for the planes, but instead a 2D (areal) representation of information. Scale bar shown in plane 198e is 3 μm, which applied to all planes shown.

FIG. 27 depicts spectral characteristics of POPO-3 and corresponding experimental data. Absorption (green) and emission (orange) data are plotted for POPO-3. The integrated fluorescence signal obtained from the combination of SHG-excitation and two-photon excitation are shown in the graph as the upper noisy curve, which diverges (on the right portion of the graph) from a lower noisy curve that depicts a trace of SHG-excitation without two-photon excitation. Considering these two traces, it will be noted that they are nearly indistinguishable from one another near the peak and on the left-side portion of the graph.

The integrated spectral intensity for composite nanowire/two-photon excitation was found to be about 2.2 times larger than the corresponding value for exclusive SHG-excitation. Consequently, the effective fluorescence intensity produced from single-photon excitation by the nanowire-probe is comparable to that of standard two-photon excitation, given that the volume of dye probed in the nanowire excitation is approximately half that of the volume involved in two-photon excitation. Presumably, this is possible because of the larger absorption cross-section for one-photon excitation.

In principle, the spatial resolution of this form of microscopy, involving the scanning of optically tapped sources of coherent light, corresponds to the nanowire diameter (˜100 nm). The spatial localization of the SHG within the nanowire has the additional advantage of reducing undesirable background fluorescence intrinsic to laser scanning confocal microscopy. Furthermore, it should be possible to make massively parallel excitation arrays using this technique with holographic optical elements. Several recent advances in light microscopy are based on controlling the structure of illumination light and the use of particular illumination protocols in conjunction with photo-activatable tags. These and other light microscopy geometries can be used in conjunction with this mobile, tunable, and coherent optical probe with subwavelength aperture and enable the imaging of biological samples beyond the diffraction limit without damage from direct laser irradiation.

### EXAMPLE 16

Potassium hydroxide and niobium pentoxide were mixed with deionized water for 2 hours at room temperature. The slurry was transferred to Teflon vessels and then heated at 150° C. for 2-6 days using the stainless autoclaves. It should be noted that nanowire sizes may be varied by adjusting reaction time. Scanning electron microscopy (SEM) images showed that the products are collections of rectangularly-shaped nanowires with widths ranging from 40 to 400 nm and the lengths from 1 to 20 μm as were represented in FIG. 15. These products were identified as the single phase orthorhombic KNbO₃ (Amm2, a=0.3984 nm, b=0.5676 nm, and c=0.5697 nm) from X-ray powder diffraction (XRD) measurements of FIG. 16. Transmission electron microscope (TEM) images and electron diffraction (ED) measurements of FIG. 17, and FIG. 18A-18B show that the nanowires grow parallel to [011] directions. Twinned structures were observed in some of the nanowires.

### EXAMPLE 17

Single nanowire suspensions were obtained after sonication in iso-propanol and placed on a transparent glass coverslip with a nanomanipulator. Femtosecond pulses generated by a regeneratively amplified Ti:sapphire oscillator (wavelength: λ=800 nm, 90 fs, 1 kHz) were used to pump an OPA where the wavelength is continuously tunable between 1150-2600 nm and can be frequency doubled by a BBO crystal outside the OPA providing access to shorter wavelengths before being introduced to the nanowire perpendicular to its growth direction, as was shown in the configuration of FIG. 19. The beam spot size was about 1 μm, which is larger than the width of the wires but smaller than their lengths. SFG spectra were measured by introducing two fundamental beams with the same polarization directions. From the experimental configuration, coefficients are identified as d_{eff}=d₃₁ for KNbO₃ nanowire, and d_{eff}=d₃₃ for ZnO nanowire.

### EXAMPLE 18

Nanowires were dispersed into deionized water inside the sample chamber. The continuous-wave IR laser (λ=1064 nm, ˜1 W) was introduced from the bottom side of the chamber to trap the nanowire as well as to generate the second harmonic wave at λ=532 nm. By way of example, the chamber can be moved coarsely with a manual stage, and finely moved with a three-axis piezostage. Color CCD images are taken at various focal planes by moving the top objective along the optical axis without translation of the trapping point, whereas spectra were taken through the bottom objective. From the experimental configuration and material properties, nonlinear optical coefficients are considered as d_{eff}=0 for both ZnO and Si nanowires. SHG signal from surface inversion symmetry breaking was too small to detect in this study.

### EXAMPLE 19

Polystyrene beads (e.g., 1 μm in diameter) containing the fluorescent dye POPO-3 (main emission peak ˜570 nm, absorption peak ˜532 nm, Molecular Probes (graph of FIG. 27) were fixed to the surface of a glass coverslip. The distal end of the trapped nanowire is brought in contact with one of the beads as was seen in representation plane 198a of FIG. 26. The initial position of the stage was set using a computer controlled piezoelectric stage, then the stage was moved away to remove the nanowire. Finally the empty laser trap was moved to the original position, where a weak green light background was seen probably due to SHG by the glass coverslip as depicted by representation plane 198d of FIG. 26. The subtraction of image plane 198d from 198c was performed using the red component of the color images. Spectra shown in FIG. 27 was obtained utilizing a sample chamber filled with a 20 vol % aqueous POPO-3 dye solution. Luminescence spectrum of SHG-excitation was obtained by subtraction of pure two-photon luminescence (without trapping a nanowire) from the one with a trapped KNbO₃ nanowire.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art. In the appended claims, reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Geometrical Characteristics, Physical Properties,
and Trapping Behaviour of Nanowires

| | | | | | Refractive |
|---|---|---|---|---|---|
| | Cross | Length | Diameter | | Index |
| Material | section | [μm] | [nm] | Trappable? | at 1064 nm |
| GaN | circular | 1-100 | 20-200 | Yes | 2.26 |
| GaN | triangular | 1-100 | 20-200 | Yes | |
| SnO₂ | rectangular | 1-100 | 200-600 | Yes^{§} | 1.94 |
| ZnO | hexagonal | 1-50 | 30-60 | Yes | 1.96 |
| Si | hexagonal | 1-15 | 10-20 | Yes | 3.6 |
| Ag | pentagonal | 1-15 | 50 | No | 6.1 |

^{§}About 7% of trapped SnO₂ wires oscillated in the trap.

What is claimed is:

1. A nanowire assembly method, comprising:
optically trapping a nanowire with an infrared single-beam optical trap; and
attaching said nanowire to an organic or inorganic structure.

2. A method as recited in claim 1, wherein said optical trap has a beam wavelength of approximately 1064 nm.

3. A method as recited in claim 1, further comprising attaching said nanowire to an organic or inorganic structure by means of laser fusing.

4. A method as recited in claim 1, wherein said nanowire has an aspect ratio greater than approximately 100.

5. A method as recited in claim 1, wherein said nanowire has a diameter less than approximately 100 nm.

6. A method as recited in claim 1, wherein said nanowire has a diameter less than approximately 80 nm.

7. A method as recited in claim 1, wherein said nanowire comprises a semiconductor.

8. A method as recited claim 1, further comprising trapping said nanowire in a fluid environment.

9. A method for nanowire laser assembly, comprising:
manipulating a nanowire with an infrared single-beam optical trap; and
assembling said nanowire into an arbitrary structure in a fluid environment.

10. A method as recited in claim 9, wherein said optical trap has a beam wavelength of approximately 1064 nm.

11. A method as recited in claim 9, further comprising attaching said nanowire to an organic or inorganic structure by means of laser fusing.

12. A method as recited in claim 9, wherein said nanowire has an aspect ratio greater than approximately 100.

13. A method as recited in claim 9, wherein said nanowire has a diameter less than approximately 100 nm.

14. A method as recited in claim 9, wherein said nanowire has a diameter less than approximately 80 nm.

15. A method as recited in claim 9, wherein said nanowire comprises a semiconductor.

16. A method as recited claim 9, further comprising trapping said nanowire in a fluid environment.

17. An assembly, comprising:
a nanowire; and
an organic or inorganic structure;
wherein said nanowire and said organic or inorganic structure are assembled by optically trapping said nanowire with an infrared single-beam optical trap, and attaching said nanowire to said organic or inorganic structure.

18. An assembly as recited in claim 17, wherein said nanowire and said organic or inorganic structure form a heterostructure.

19. An assembly as recited in claim 17, wherein said optical trap has a beam wavelength of approximately 1064 nm.

20. An assembly as recited in claim 17, where said nanowire is attached to said organic or inorganic structure by means of laser fusing.

21. An assembly as recited in claim 17, wherein said nanowire has an aspect ratio greater than approximately 100.

22. An assembly as recited in claim 17, wherein said nanowire has a diameter less than approximately 100 nm.

23. An assembly as recited in claim 17, wherein said nanowire has a diameter less than approximately 80 nm.

24. An assembly as recited in claim 17, wherein said nanowire comprises a semiconductor.

25. A nanowire assembly, comprising:
a nanowire; and
an arbitrary structure;
wherein said nanowire is manipulated with an infrared single-beam optical trap and assembled into said arbitrary structure in a fluid environment.

26. An assembly as recited in claim 25, wherein said nanowire and said arbitrary structure form a heterostructure.

27. An assembly as recited in claim 25, wherein said optical trap has a beam wavelength of approximately 1064 nm.

28. An assembly as recited in claim 25, where said nanowire is attached to said arbitrary structure by means of laser fusing.

29. An assembly as recited in claim 25, wherein said nanowire has an aspect ratio greater than approximately 100.

30. An assembly as recited in claim 25, wherein said nanowire has a diameter less than approximately 100 nm.

31. An assembly as recited in claim 25, wherein said nanowire has a diameter less than approximately 80 nm.

32. An assembly as recited in claim 25, wherein said nanowire comprises a semiconductor.
